(19) United States
(12) Patent Application Publication
(10) Pub. No.: US 2025/0105106 A1
(43) Pub. Date: Mar. 27, 2025

(54) SEMICONDUCTOR DEVICES AND METHODS FOR MANUFACTURING THEREOF

(71) Applicant: Infineon Technologies AG, Neubiberg (DE)

(72) Inventors: Sheila Dimol RODRIGUEZ, Singapore (SG); Kok Kiat KOO, Singapore (SG); Dexter Inciong REYNOSO, Singapore (SG); Mary Grace Mercado PLATA, Singapore (SG)

(73) Assignee: Infineon Technologies AG, Neubiberg (DE)

(21) Appl. No.: 18/828,781

(22) Filed: Sep. 9, 2024

(30) Foreign Application Priority Data
Sep. 26, 2023 (DE) 10 2023 126 119.3

(51) Int. Cl. H01L 23/495; H01L 21/56; H01L 23/31; H01L 25/00; H01L 25/065

(52) U.S. Cl. CPC H01L 23/49555; H01L 23/3107; H01L 23/49575; H01L 25/0655; H01L 25/50; H01L 21/56

(57) ABSTRACT

A semiconductor device is disclosed. In one example, the semiconductor device includes an encapsulation material at least partially encapsulating a semiconductor component of the semiconductor device. The semiconductor device further includes a first lead protruding out of a first side surface of the encapsulation material and a second lead protruding out of a second side surface of the encapsulation material opposite to the first side surface. The first lead includes a first notch aligned with the first side surface of the encapsulation material. The first notch faces away from a further lead protruding out of the first side surface of the encapsulation material.

### CROSS-REFERENCE TO RELATED APPLICATION

This Utility Patent application claims priority to German Patent Application No. 10 2023 126 119.3 filed Sep. 26, 2023, which is incorporated herein by reference.

### TECHNICAL FIELD

The present disclosure relates to semiconductor devices and methods for manufacturing such semiconductor devices.

### BACKGROUND

Semiconductor devices and applications using them may need to comply with electrical isolation requirements defined by associated safety standards. One or multiple components of a semiconductor device may be encapsulated in a package body. In order to guarantee safe operation of the semiconductor device and to comply with said electrical isolation requirements, one or multiple minimum creepage distances between conductive parts protruding out of the package body may need to be provided.

Manufacturers and developers of semiconductor devices are constantly striving to improve their products and methods for manufacturing thereof. In this regard, it may be desirable to provide semiconductor devices with improved electrical and isolation performances. In particular, it may be desirable to protect the semiconductor devices from harmful creepage along surfaces of the package body. It may further be desirable to provide suitable methods for manufacturing such semiconductor devices.

### SUMMARY

An aspect of the present disclosure relates to a semiconductor device. The semiconductor device comprises an encapsulation material at least partially encapsulating a semiconductor component of the semiconductor device. The semiconductor device further comprises a first lead protruding out of a first side surface of the encapsulation material and a second lead protruding out of a second side surface of the encapsulation material opposite to the first side surface. The first lead comprises a first notch aligned with the first side surface of the encapsulation material. The first notch faces away from a further lead protruding out of the first side surface of the encapsulation material.

A further aspect of the present disclosure relates to a semiconductor device. The semiconductor device comprises an encapsulation material at least partially encapsulating a semiconductor component of the semiconductor device. The semiconductor device further comprises a first lead protruding out of a first side surface of the encapsulation material and a second lead protruding out of a second side surface of the encapsulation material opposite to the first side surface. A cross section of the first lead tapers towards the first side surface of the encapsulation material.

A further aspect of the present disclosure relates to a method for manufacturing a semiconductor device. The method comprises an act of providing a semiconductor component. The method further comprises an act of providing a first lead and a second lead, wherein the first lead comprises a first notch. The method further comprises an act of at least partially encapsulating the semiconductor component, the first lead and the second lead in the encapsulation material. The first lead protrudes out of a first side surface of the encapsulation material, and the second lead protrudes out of a second side surface of the encapsulation material opposite to the first side surface. The first notch is aligned with the first side surface of the encapsulation material. The first notch faces away from a further lead protruding out of the first side surface of the encapsulation material.

A further aspect of the present disclosure relates to a method for manufacturing a semiconductor device. The method comprises an act of providing a semiconductor component. The method further comprises an act of providing a first lead and a second lead. The method further comprises an act of at least partially encapsulating the semiconductor component, the first lead and the second lead in the encapsulation material. The first lead protrudes out of a first side surface of the encapsulation material, and the second lead protrudes out of a second side surface of the encapsulation material opposite to the first side surface. A cross section of the first lead tapers towards the first side surface of the encapsulation material.

### BRIEF DESCRIPTION OF THE DRAWINGS

Devices and methods in accordance with the disclosure are described in more detail below based on the drawings. The elements of the drawings are not necessarily to scale relative to each other. Similar reference numerals may designate corresponding similar parts. The technical features of the various illustrated examples may be combined unless they exclude each other and/or can be selectively omitted if not described to be necessarily required.

FIG. 1 schematically illustrates a perspective view of a semiconductor device 100.

FIG. 2 schematically illustrates a top view of a semiconductor device 200 in accordance with the disclosure and a detail thereof.

FIG. 3 schematically illustrates a top view of a semiconductor device 300 in accordance with the disclosure.

FIG. 4 schematically illustrates a top view of a semiconductor device 400 in accordance with the disclosure.

FIG. 5 schematically illustrates a top view of a semiconductor device 500 in accordance with the disclosure.

FIG. 6 schematically illustrates a top view of a semiconductor device 600 in accordance with the disclosure.

FIG. 7 schematically illustrates a top view of a semiconductor device 700 in accordance with the disclosure.

FIG. 8 illustrates a flowchart of a method for manufacturing a semiconductor device in accordance with the disclosure.

FIG. 9 illustrates a flowchart of a method for manufacturing a semiconductor device in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

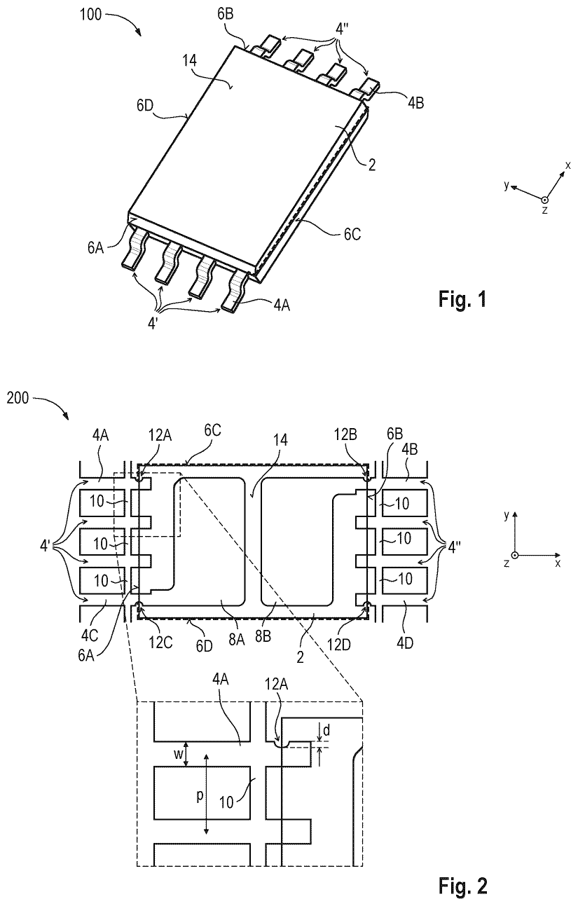

The semiconductor device 100 of FIG. 1 may include an encapsulation material 2 at least partially encapsulating one or more semiconductor components (not illustrated) of the semiconductor device 100. In addition, the semiconductor device 100 may include a first plurality of first leads (or lead fingers or pins) 4′ protruding out of a first side surface 6A of the encapsulation material 2 and a second plurality of second leads (or lead fingers or pins) 4″ protruding out of a second side surface 6B of the encapsulation material 2 opposite to the first side surface 6A. In the illustrated example, an internal structure of the semiconductor device 100 is not shown for the sake of simplicity.

The encapsulation material 2 may further include a third side surface 6C and a fourth side surface 6D opposite to the third side surface 6C. Each of the third side surface 6C and the fourth side surface 6D may connect the first side surface 6A and the second side surface 6B of the encapsulation material 2. In the illustrated example, each of the third side surface 6C and the fourth side surface 6D may be free of any leads protruding out of the encapsulation material 2. Each of the four side surfaces 6A to 6D may extend between a top surface 14 and an opposite bottom surface of the encapsulation material 2. In the chosen perspective of FIG. 1 the bottom surface is not visible.

During an operation of the semiconductor device 100 an electrical potential of a lead 4A of the first plurality of leads 4′ closest to the third side surface 6C may differ from an electrical potential of a lead 4B of the second plurality of leads 4″ closest to the third side surface 6C. If a creepage distance between the first lead 4A and the second lead 4B is too small, a leakage current path may form on the surface of the encapsulation material 2. A creepage distance may be specified as shortest distance along the surface of a (solid) insulating material between two conductive parts. In the illustrated example, the creepage distance between the leads 4A and 4B is indicated by a dashed line. If the leakage current path constitutes a conductive path, a short circuit between the leads 4A and 4B may occur and the semiconductor device 100 may be damaged.

Sufficiently large creepage distances may be regarded as one of the key requirements in developing semiconductor devices, such as e.g. gate drivers, isolated drivers, digital isolators, current sensors, auxiliary power components, or the like. The longer the provided creepage distances of the semiconductor devices, the more competitive the developed products may be. However, due to decreasing package sizes, achieving increased creepage distances may become a design challenge.

The semiconductor device 200 of FIG. 2 may include some or all features of the semiconductor device 100 of FIG. 1. The semiconductor device 200 may include an encapsulation material 2, a first plurality of first leads 4′, a second plurality of second leads 4″, a first diepad 8A and a second diepad 8B. In the illustrated example, the encapsulation material 2 may include four side surfaces 6A to 6D. The first plurality of first leads 4′ may protrude out of the first side surface 6A, while the second plurality of second leads 4″ may protrude out of the second side surface 6B opposite to the first side surface 6A. Each of the third side surface 6C and the fourth side surface 6D may connect the first side surface 6A and the second side surface 6B and may be free of any leads protruding out of the encapsulation material 2. The semiconductor device 200 may thus correspond to a dual-sided semiconductor device (or dual-sided semiconductor package). It is to be noted that, in practice, the diepads 8A and 8B may be covered by the (in particular opaque) encapsulation material 2 and may thus be not be visible.

The semiconductor device 200 may include one or more semiconductor components which may be arranged on one or both of the diepads 8A and 8B. In the illustrated example, the semiconductor components are not shown for the sake of simplicity. In particular, the semiconductor components may include or may correspond to semiconductor chips. Throughout this description the terms “chip”, “semiconductor chip”, “die”, “semiconductor die” may be used interchangeably. The semiconductor chips may be manufactured from an elemental semiconductor material (e.g. Si) or from a wide band gap semiconductor material or a compound semiconductor material (e.g. SiC, GaN, SiGe, GaAs). The semiconductor chips may be of arbitrary types and may include integrated circuits with active electronic components and/or passive electronic components. The integrated circuits may be designed as logic integrated circuits, analog integrated circuits, mixed signal integrated circuits, power integrated circuits, memory circuits, integrated passives, etc. For example, semiconductor chips of the semiconductor device 200 may be configured to operate as one of a gate driver, an isolated driver, a digital isolator, a current sensor, an auxiliary power component, or the like.

One or more of the semiconductor chips may correspond to power semiconductor components and may thus be referred to as power semiconductor chips. In this context, the term “power semiconductor chip” may refer to a semiconductor chip providing at least one of high voltage blocking or high current-carrying capabilities. A power semiconductor chip may be configured for high currents having a maximum current value of a few Amperes, such as e.g. 10A, or a maximum current value of up to or exceeding 100A. Similarly, voltages associated with such current values may have values of a few Volts to a few tens or hundreds of Volts. One or more of the semiconductor chips may correspond to logic semiconductor chips. A logic semiconductor chip may be configured to e.g. drive and/or control one or more power semiconductor chips, for example via a gate terminal of a power transistor chip. Some logic semiconductor chips may thus be referred to as driver semiconductor chips (or drivers) or control semiconductor chips (or controllers).

The leads 4′, 4″ and the diepads 8A, 8B may be part of a leadframe. The leadframe may be structured such that the leads 4′, 4″ and the diepads 8A, 8B may be formed from the material of the leadframe. In the illustrated non-limiting case, an exemplary number of two diepads 8A, 8B and an exemplary number of four leads 4′, 4″ on each of the side surfaces 6A, 6B of the encapsulation material 2 are shown. In further examples, the number of diepads and leads may differ and may particularly depend on the specific type and functionality of the semiconductor device 200. In the illustrated example, the two pluralities of leads 4′, 4″ may correspond to two (in particular linear) rows of leads protruding out of the opposite side surfaces 4A and 4B of the encapsulation material 2 and having a lead pitch p. One or both of the diepads 8A, 8B may be configured as a carrier for one or more semiconductor components. Throughout this description the terms “diepad” and “die paddle” may be used interchangeably.

The leadframe (and thus the leads 4′, 4″ and the diepads 8A, 8B) may be fabricated from metals and/or metal alloys, in particular at least one of copper, copper alloys, nickel, iron nickel, aluminum, aluminum alloys, steel, stainless steel, or the like. During a fabrication of the semiconductor device 200, the leads 4′, 4″ and the diepads 8A, 8B may be connected to each other. In particular, the leads 4′, 4″ and the diepads 8A, 8B may be made from one piece during fabrication. The leads 4′, 4″ and the diepads 8A, 8B may be connected among each other by connection means with the purpose of separating some of the diepads and the leads in the course of the fabrication.

The semiconductor device 200 of FIG. 2 may (not yet) be separated from other semiconductor devices manufactured in the same batch process. In the illustrated example, the semiconductor device 200 may still include multiple dambars 10 connecting neighboring leads. Dambars may be used in leadframe designs to facilitate a molding or encapsulation act and further to provide support for leads of the leadframe. During the encapsulation act the dambars may be configured to function as a clamping surface for edges of a mold tool and as a barrier to prevent leakage or flashing of the mold material from the mold tool onto the leads. It is noted that the dambars 10 may be removed later on so that the leads 4′, 4″ may be physically and/or electrically individualized depending on their respective functionality.

The encapsulation material 2 may at least partially encapsulate one or more of the leads 4′, 4″, the diepads 8A, 8B and the semiconductor components of the semiconductor device 200. The encapsulation material 2 may include or may be manufactured from at least one of an epoxy, a filled epoxy, a glass fiber filled epoxy, an imide, a thermoplast, a thermoset polymer, a polymer blend, a laminate, or the like. Various techniques may be used for encapsulating components of the semiconductor device 200 with the encapsulation material 2, for example at least one of compression molding, injection molding, powder molding, liquid molding, map molding, laminating, or the like.

In the illustrated example, the encapsulation material 2 may form a body or encapsulant having a top surface 14, an opposite bottom surface (not visible) and four side surfaces 6A to 6D extending between the top surface 14 and the bottom surface. Due to such packaging the semiconductor device 200 may be referred to as semiconductor package. The leads 4′ and 4″ may at least partially protrude out of the encapsulation material 2 such that encapsulated semiconductor components may be electrically accessible from outside of the encapsulation material 2. In one example, the diepads 8A and 8B may be completely encapsulated in the encapsulation material 2. The bottom surfaces of the diepads 8A and 8B may be (in particular fully) covered by the encapsulation material 2.

The first plurality of leads 4′ may include a first lead 4A closest to the third side surface 6C of the encapsulation material 2 and protruding out of the first side surface 6A of the encapsulation material 2. In a similar fashion, the second plurality of leads 4″ may include a second lead 4B closest to the third side surface 6C of the encapsulation material 2 and protruding out of the second side surface 6B of the encapsulation material 2. Due to their locations the leads 4A and 4B may be referred to as corner leads. In the illustrated example, the first lead 4A may be separate and electrically insulated from the first diepad 8A. In this regard, the electrically insulating encapsulation material 2 may be configured to provide an electrical isolation between the first lead 4A and the first diepad 8A. The second lead 4B may be electrically connected to the second diepad 8B. In this regard, the second lead 4B and the second diepad 8B may be made of a single piece of metal or metal alloy.

At least one first semiconductor chip (not illustrated) may be arranged over the first diepad 8A. One or more leads 4′ (and in particular the first lead 4A) may be electrically connected to the at least one first semiconductor chip via one or more electrical connection elements (not illustrated), such as e.g. a wire, a clip, a ribbon, or the like. In addition, at least one second semiconductor chip (not illustrated) may be arranged over the second diepad 8B. In a similar fashion, one or more leads 4″ (and in particular the second lead 4B) may be electrically connected to the at least one second semiconductor chip. In some examples, the at least one first semiconductor chip and the at least one second semiconductor chip may be configured to operate as a gate driver, an isolated driver, a digital isolator, a current sensor, or an auxiliary power component.

The at least one first semiconductor chip and the first lead 4A may be configured to operate in a low voltage domain. For example, a low voltage domain may be associated with or may be specified by an exemplary value range from about 0V to about 20V. In this regard, typical exemplary operating values of a low voltage domain may be about 3.3V or about 5V. The at least one second semiconductor chip and the second lead 4B may be configured to operate in a high voltage domain. For example, a high voltage domain may be associated with or may be specified by an exemplary value range from about 50V to about 15000V. In this regard, typical exemplary operating values of a high voltage domain may be about 600V or about 800V or about 1200V.

One or more of the leads 4′ (and in particular the first lead 4A) may be configured as an input (or input pins or input terminals) of the semiconductor device 200. In addition, one or more of the leads 4″ (and in particular the second lead 4B) may be configured as an output (or output pins or output terminals) of the semiconductor device 200. In one example, the input leads of the semiconductor device 200 may operate in a high voltage domain, while the output leads may operate in a low voltage domain.

Since the first lead 4A and the second lead 4B may operate at different voltage domains (e.g. at a high voltage domain and a low voltage domain), a sufficiently large creepage distance between the first lead 4A and the second lead 4B may be required. In this regard, it is to be noted that a sufficient value of the first creepage distance between the leads 4A and 4B may depend on a maximum operating voltage of the semiconductor device 200. The higher the maximum operating voltage, the higher the first creepage distance may need to be. In an exemplary and in no way limiting case, a maximum operating voltage of the semiconductor device 200 may have a value of about 600V. Here, a sufficient length of the first creepage distance may e.g. have a value of about 8 mm. In the illustrated example, the first creepage distance between the corner leads 4A and 4B is indicated by a dashed line. The first creepage distance may extend from the first lead 4A along a portion of the first side surface 6A, further along the entire third side surface 6C and further along a portion of the second side surface 6B to the second lead 4B.

The first lead 4A may include a first notch (or recess or groove) 12A that may be aligned with the first side surface 6A of the encapsulation material 2. In the top view of FIG. 2, the first notch 12A and the first side surface 6A may be arranged in line. The first notch 12A may face in a direction towards the third side surface 6C. The first notch 12A may face away from the other leads protruding out of the first side surface 6A of the encapsulation material 2. In particular, the first notch 12A may face away from the lead that is arranged (directly) adjacent to the first lead 4A.

The first notch 12A may be only partially arranged inside the encapsulation material 2. A first portion of the first notch 12A may be arranged outside of the encapsulation material 2, while a second portion of the first notch 12A may be encapsulated in the encapsulation material 2. Due to such partial arrangement in the encapsulation material 2, the first notch 12A may be configured to provide an interlocking between the first lead 4A and the encapsulation material 2. Such interlocking feature (or mold locking feature) may result in a firm and stable mechanical connection between the lead 4A and the encapsulation material 2.

The first notch 12A may be configured to increase the first creepage distance between the first lead 4A and the second lead 4B compared to a same semiconductor device not including the first notch 12A. Using the first notch 12A in the first lead 4A may thus reduce a risk of leakage currents and short circuits between the first lead 4A and the second lead 4B. Safe operation of the semiconductor device 200 and compliance with electrical isolation requirements may thus be guaranteed. In addition, increased creepage distances may provide the possibility of further reducing the size of the semiconductor package 200, in particular the length of the package body 2 in the x-direction. It is to be noted that increasing the first creepage distance when using the first notch 12A may be achieved without a need of major changes in the design of the semiconductor package 200, such as changes in e.g. lead width, lead pitch, mold body, etc. In particular, the first creepage distance may be increased without a need to change the footprint of the semiconductor device 200.

A shape or form of the first notch 12A may be chosen arbitrarily as long as it may result in an increase of the first creepage distance between the corner leads 4A and 4B. In the exemplary top view of FIG. 2, the first notch 12A may be c-shaped. In further examples, the first notch 12A may be v-shaped, u-shaped, square-shaped, rectangular-shaped, semi-circular, semi-elliptical, tapered, or the like, when viewed in a direction perpendicular to the top surface 14.

A depth d of the first notch 12A may depend on a width w of the first lead 4A. A minimum depth of the first notch 12A may have a value of about 0.15 mm, while a maximum depth of the first notch 12A may have a value of about 30% of the width w of the first lead 4A. By providing the first notch 12A, the first creepage distance between the first lead 4A and the second lead 4B may be increased by a value corresponding to the depth d of the first notch 12A. In the illustrated example, the first notch 12A may have the shape of a semi-circle. An exemplary and non-limiting value of the radius of such semi-circle may be about 0.2 mm.

The second lead 4B may include a second notch 12B that may be aligned with the second side surface 6B of the encapsulation material 2. The second notch 4B may be similar to the first notch 12A such that all previous comments regarding the first notch 12A may also hold true for the second notch 12B. In particular, the second notch 12B may be configured to further increase the first creepage distance between the first lead 4A and the second lead 4B along the third side surface 6C of the encapsulation material 2.

The first plurality of leads 4′ may include a third lead 4C closest to the fourth side surface 6D of the encapsulation material 2 and protruding out of the first side surface 6A of the encapsulation material 2. In a similar fashion, the second plurality of leads 4″ may include a fourth lead 4D closest to the fourth side surface 6D of the encapsulation material 2 and protruding out of the second side surface 6B of the encapsulation material 2. The leads 4C and 4D may be referred to as corner leads and may be similar to the previously described first lead 4A and second lead 4B. In the illustrated example, the third lead 4C may be electrically connected to the first diepad 8A. In this regard, the third lead 4C and the first diepad 8A may be made of a single piece of metal or metal alloy. The fourth lead 4D may be separate and electrically insulated from the second diepad 8B. In this regard, the electrically insulating encapsulation material 2 may be configured to provide an electrical isolation between the fourth lead 4D and the second diepad 8B.

The third lead 4C may include a third notch 12C that may be aligned with the first side surface 6A of the encapsulation material 2. The third notch 4C may e.g. be similar to the first notch 12A previously described. The third notch 12C may be configured to increase a second creepage distance between the third lead 4C and the fourth lead 4D. The second creepage distance may extend from the third lead 4C along a portion of the first side surface 6A, further along the entire fourth side surface 6D and further along a portion of the second side surface 6B to the fourth lead 4D. In the illustrated example, the second creepage distance between the corner leads 4C and 4D is indicated by a dashed line.

The fourth lead 4B may include a fourth notch 12D that may be aligned with the second side surface 6B of the encapsulation material 2. The fourth notch 4D may e.g. be similar to the second notch 12B previously described. In particular, the fourth notch 12D may be configured to further increase the second creepage distance between the corner leads 4C and 4D along the fourth side surface 6D of the encapsulation material 2.

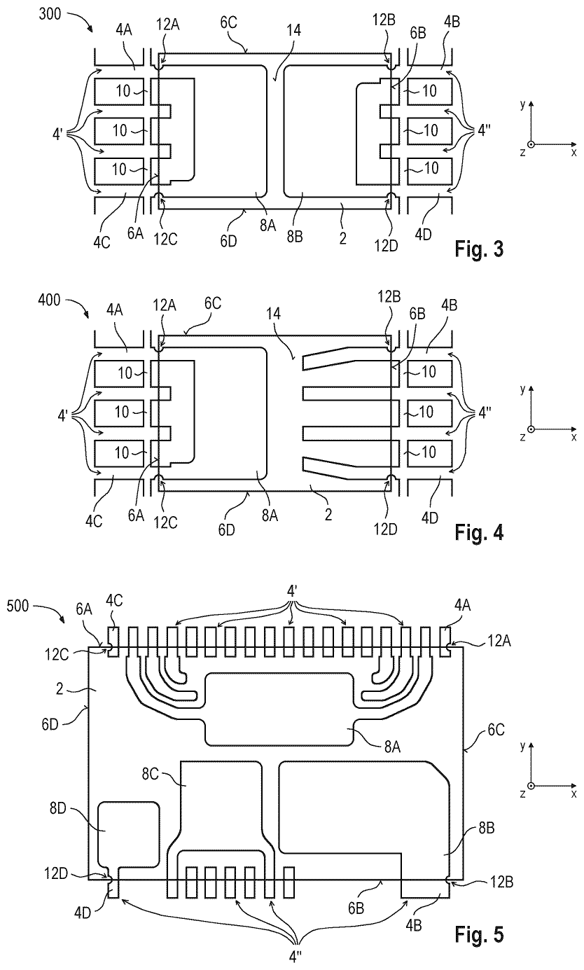

The semiconductor device 300 of FIG. 3 may include some or all features of previously described semiconductor devices. In contrast to the example of FIG. 2, the first lead 4A may be electrically connected to the first diepad 8A. In this context, the first lead 4A and the first diepad 8A may be made of a single piece of metal or metal alloy. In further contrast to the example of FIG. 2, the fourth lead 4D may be electrically connected to the second diepad 8B. In this context, the fourth lead 4D and the second diepad 8B may be made of a single piece of metal or metal alloy. Accordingly, in the illustrated example, each of the four corner leads 4A to 4D may be electrically connected to one of the diepads 8A and 8B.

The semiconductor device 400 of FIG. 4 may include some or all features of previously described semiconductor devices. In contrast to the examples of FIGS. 2 and 3, the semiconductor device 400 may include only one diepad 8 which may be similar to the diepad 8A of FIGS. 2 and 3 in particular. Furthermore, the second plurality of leads 4″ may extend further into the encapsulation material 2 as shown in previous examples. The portions of the corner leads 4B and 4D extending into the encapsulation material 2 may be at least partially bent inwards. Similar to previous examples, each of the four corner leads 4A to 4D may include a notch configured to increase a respective creepage distance between leads.

The semiconductor device 500 of FIG. 5 may include some or all features of previously described semiconductor devices. In contrast to previous examples, the semiconductor device 500 may include a larger number of diepads. In the illustrated case, the semiconductor device 500 may include an exemplary number of four diepads 8A to 8D. A first diepad 8A may be arranged at the first side surface 6A of the encapsulation material 2, while the other three diepads 8B to 8D may be arranged at the second side surface 6B of the encapsulation material 2 opposite to the first side surface 6A. The first plurality of leads 4′ may protrude out of the first side surface 6A. One or more of the leads 4′ may be electrically connected to the first diepad 8A. These leads and the first diepad 8A may be made of a single piece of metal or metal alloy. In the illustrated example, the first corner lead 4A and the third corner lead 4C may be separate and electrically insulated from the first diepad 8A.

The second plurality of leads 4″ may protrude out of the second side surface 6B of the encapsulation material 2. The second corner lead 4B may be arranged at the third side surface 6C of the encapsulation material 2 connecting the first side surface 6A and the second side surface 6B. The second lead 4B may be electrically connected to the second diepad 8B. In a similar fashion, the fourth corner lead 4D may be arranged at the fourth side surface 6D of the encapsulation material 2 connecting the first side surface 6A and the second side surface 6B. The fourth lead 4D may be electrically connected to the fourth diepad 8D. One or more of the remaining leads 4″ may be electrically connected to a third diepad 8C that may be arranged between the second diepad 8B and the fourth diepad 8D. In the illustrated example, each of the four corner leads 4A to 4D may include a notch such that respective creepage distances between corresponding leads may be increased and isolation properties of the semiconductor device 500 may be improved.

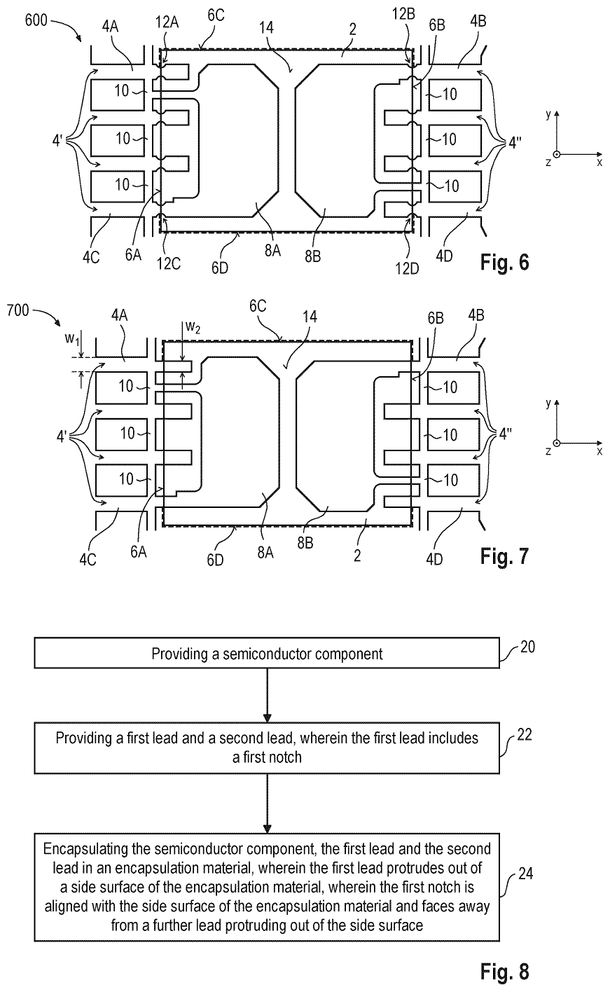

The semiconductor device 600 of FIG. 6 may include some or all features of previously described semiconductor devices. In previous examples, the first lead 4A may have included a first notch 12A facing away from a further lead protruding out of the same first side surface 6A of the encapsulation material 2. In contrast to this, the first notch 12A of FIG. 6 may not only be formed in a side of the first lead 4A facing away from neighboring leads, but may extend around the entire circumference of the first lead 4A. For example, the first notch 12A may be a radial or ring-shaped notch that may extend completely around the first lead 4A. One or more of the additional corner leads 4B to 4D may be designed in a similar fashion and may also include a respective notch. In the illustrated example, similar notches 12B to 12D may be formed in each of the additional three corner leads 4B to 4D.

The semiconductor device 700 of FIG. 7 may include some or all features of previously described semiconductor devices. The semiconductor device 700 may include an encapsulation material 2 at least partially encapsulating a semiconductor component (not illustrated) of the semiconductor device 700. A first lead 4A may protrude out of a first side surface 6A of the encapsulation material 2, while a second lead 4B may protrude out of a second side surface 6B of the encapsulation material 2 opposite to the first side surface 6A.

A cross section (or a cross-sectional area) of the first lead 4A may be associated with a sectional plane that may extend substantially parallel to the y-z plane. A cross section of the first lead 4A may taper towards the first side surface 6A of the encapsulation material 2. That is, a cross-sectional area of the first lead 4A associated with sectional planes substantially parallel to the y-z plane may decrease in a direction towards the first side surface 6A. In the exemplary top view of FIG. 7, the first lead 4A may have a non-uniform lead width. In particular, the first lead 4A may include a first portion having a first width w₁ and a second portion having a second width w₂ smaller than the first width w₁, wherein the second portion may be arranged closer to the first side surface 6A than the first portion. In the illustrated example, the first portion of the first lead 4A may be arranged to the left of the dambar 10, while the second portion of the first lead 4A may be arranged to the right of the dambar 10. Due the decreasing width towards the first side surface 6A, a cross section of the first lead 4A may taper.

The described tapering of the first lead 4A towards the first side surface 4A may result in an increase of a creepage distance between the first lead 4A and the second lead 4B along the third side surface 6C of the encapsulation material 2. One or more of the three further corner leads 4B to 4D may be similar to the first corner lead 4A and may also taper towards a respective side surface of the encapsulation material 2, thereby increasing creepage distances between respective corner leads.

It is to be noted that the example of FIG. 7 may be combined with any one of the other examples discussed herein. That is, in further examples, one or more of the corner leads 4A to 4D may include both a notch and a tapered form towards the side surface out of which the respective corner lead protrudes.

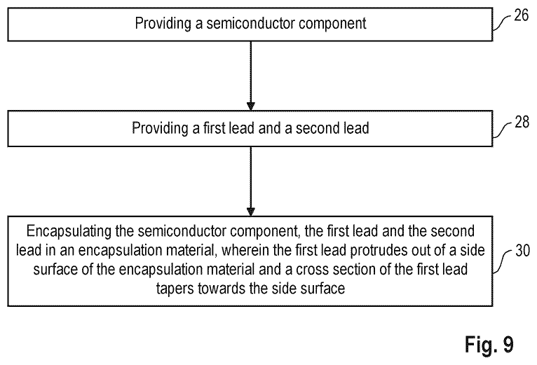

FIGS. 8 and 9 illustrate flowcharts of methods for manufacturing semiconductor devices in accordance with the disclosure. The methods of FIGS. 8 and 9 are described in a general manner in order to qualitatively specify aspects of the present disclosure. The methods may include further aspects. For example, the methods may be extended by any aspect described herein in connection with other examples. In particular, the methods may be used for manufacturing previously described semiconductor devices in accordance with the disclosure.

FIG. 8 illustrates a first method for manufacturing a semiconductor device. For example, the method of FIG. 8 may be used for manufacturing any of the semiconductor devices of FIGS. 2 to 6. At 20, a semiconductor component may be provided. At 22, a first lead and a second lead may be provided, wherein the first lead includes a first notch. At 24, the semiconductor component, the first lead and the second lead may be at least partially encapsulated in the encapsulation material. The first lead may protrude out of a first side surface of the encapsulation material, and the second lead may protrude out of a second side surface of the encapsulation material opposite to the first side surface. The first notch may be aligned with the first side surface of the encapsulation material. The first notch may face away from a further lead protruding out of the first side surface of the encapsulation material.

FIG. 9 illustrates a second method for manufacturing a semiconductor device. For example, the method of FIG. 9 may be used for manufacturing the semiconductor device of FIG. 7. At 26, a semiconductor component may be provided. At 28, a first lead and a second lead may be provided. At 30, the semiconductor component, the first lead and the second lead may be at least partially encapsulated in the encapsulation material. The first lead may protrude out of a first side surface of the encapsulation material, and the second lead may protrude out of a second side surface of the encapsulation material opposite to the first side surface. A cross section of the first lead may taper towards the first side surface of the encapsulation material.

### EXAMPLES

In the following, semiconductor devices in accordance with the disclosure and methods for manufacturing such semiconductor devices are described by means of examples.

Example 1 is a semiconductor device, comprising: an encapsulation material at least partially encapsulating a semiconductor component of the semiconductor device; a first lead protruding out of a first side surface of the encapsulation material; and a second lead protruding out of a second side surface of the encapsulation material opposite to the first side surface, wherein the first lead comprises a first notch aligned with the first side surface of the encapsulation material, and wherein the first notch faces away from a further lead protruding out of the first side surface of the encapsulation material.

Example 2 is a semiconductor device according to Example 1, wherein a first portion of the first notch is arranged outside of the encapsulation material and a second portion of the first notch is encapsulated in the encapsulation material.

Example 3 is a semiconductor device according to Example 1 or 2, wherein the first notch is configured to increase a first creepage distance between the first lead and the second lead, the first creepage distance extending at least partially along the first side surface of the encapsulation material, along a third side surface of the encapsulation material connecting the first side surface and the second side surface of the encapsulation material, and at least partially along the second side surface of the encapsulation material.

Example 4 is a semiconductor device according to Example 3, wherein the third side surface of the encapsulation material is free of any leads protruding out of the encapsulation material.

Example 5 is a semiconductor device according to one of the preceding Examples, wherein: the first side surface and the second side surface are adjacent to a top surface of the encapsulation material, and the first notch is one of c-shaped, v-shaped, square-shaped, rectangular-shaped, or tapered when viewed in a direction perpendicular to the top surface.

Example 6 is a semiconductor device according to one of the preceding Examples, wherein the first notch extends around the entire circumference of the first lead.

Example 7 is a semiconductor device according to one of the preceding Examples, wherein the first notch is configured to provide an interlocking between the first lead and the encapsulation material.

Example 8 is a semiconductor device according to one of the preceding Examples, wherein a minimum depth of the first notch is 0.15 mm and a maximum depth of the first notch is 30% of a width of the first lead.

Example 9 is a semiconductor device according to one of Examples 3 to 8, wherein: the second lead comprises a second notch aligned with the second side surface of the encapsulation material, and the second notch is configured to increase the first creepage distance between the first lead and the second lead along the third side surface of the encapsulation material.

Example 10 is a semiconductor device according to one of Examples 3 to 9, comprising: a first plurality of leads protruding out of the first side surface of the encapsulation material, wherein the first lead is the lead of the first plurality of leads closest to the third side surface of the encapsulation material; and a second plurality of leads protruding out of the second side surface of the encapsulation material, wherein the second lead is the lead of the second plurality of leads closest to the third side surface of the encapsulation material.

Example 11 is a semiconductor device according to one of the preceding Examples, wherein one of the first lead and the second lead is configured to operate in a low voltage domain and the other one of the first lead and the second lead is configured to operate in a high voltage domain.

Example 12 is a semiconductor device according to one of the preceding Examples, wherein one of the first lead and the second lead is configured as an input of the semiconductor device and the other one of the first lead and the second lead is configured as an output of the semiconductor device.

Example 13 is a semiconductor device according to one of the preceding Examples, comprising: a first diepad, wherein one of the first lead and the second lead is separate and electrically insulated from the first diepad; and a second diepad, wherein the other one of the first lead and the second lead is electrically connected to the second diepad, and wherein the second diepad and the other one of the first lead and the second lead are made of a single piece of metal or metal alloy.

Example 14 is a semiconductor device according to Example 13, comprising: at least one first semiconductor chip arranged over the first diepad, and at least one second semiconductor chip arranged over the second diepad, wherein the at least one first semiconductor chip and the at least one second semiconductor chip are configured to operate as a gate driver, an isolated driver, a digital isolator, a current sensor, or an auxiliary power component.

Example 15 is a semiconductor device according to one of Examples 3 to 14, comprising: a third lead protruding out of the first side surface of the encapsulation material; and a fourth lead protruding out of the second side surface of the encapsulation material, wherein the third lead comprises a third notch aligned with the first side surface of the encapsulation material, wherein the fourth lead comprises a fourth notch aligned with the second side surface of the encapsulation material, and wherein the third notch and the fourth notch are configured to increase a second creepage distance between the third lead and the fourth lead, the second creepage distance extending at least partially along the first surface of the encapsulation material, along a fourth side surface of the encapsulation material opposite to the third side surface of the encapsulation material, the fourth side surface connecting the first side surface and the second side surface of the encapsulation material, and at least partially along the second side surface of the encapsulation material.

Example 16 is a semiconductor device according to Example 15, wherein the fourth side surface of the encapsulation material is free of any leads protruding out of the encapsulation material.

Example 17 is a semiconductor device according to Example 15 or 16, wherein: the third lead is the lead of the first plurality of leads closest to the fourth side surface of the encapsulation material, and the fourth lead is the lead of the second plurality of leads closest to the fourth side surface of the encapsulation material.

Example 18 is a semiconductor device, comprising: an encapsulation material at least partially encapsulating a semiconductor component of the semiconductor device; a first lead protruding out of a first side surface of the encapsulation material; and a second lead protruding out of a second side surface of the encapsulation material opposite to the first side surface, wherein a cross section of the first lead tapers towards the first side surface of the encapsulation material.

Example 19 is a method for manufacturing a semiconductor device, the method comprising: providing a semiconductor component; providing a first lead and a second lead, wherein the first lead comprises a first notch; and at least partially encapsulating the semiconductor component, the first lead and the second lead in the encapsulation material, wherein the first lead protrudes out of a first side surface of the encapsulation material, wherein the second lead protrudes out of a second side surface of the encapsulation material opposite to the first side surface, wherein the first notch is aligned with the first side surface of the encapsulation material, and wherein the first notch faces away from a further lead protruding out of the first side surface of the encapsulation material.

Example 20 is a method for manufacturing a semiconductor device, the method comprising: providing a semiconductor component; providing a first lead and a second lead; and at least partially encapsulating the semiconductor component, the first lead and the second lead in the encapsulation material, wherein the first lead protrudes out of a first side surface of the encapsulation material, wherein the second lead protrudes out of a second side surface of the encapsulation material opposite to the first side surface, and wherein a cross section of the first lead tapers towards the first side surface of the encapsulation material.

As employed in this specification, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the word “over” used with regard to e.g. a material layer formed or located “over” a surface of an object may be used herein to mean that the material layer may be located (e.g. formed, deposited, etc.) “directly on”, e.g. in direct contact with, the implied surface. The word “over” used with regard to e.g. a material layer formed or located “over” a surface may also be used herein to mean that the material layer may be located (e.g. formed, deposited, etc.) “indirectly on” the implied surface with e.g. one or multiple additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the previous instances. In addition, the articles “a” and “an” as used in this application and the appended claims may generally be construed to mean “one or multiple” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures.

Although the disclosure has been shown and described with respect to one or multiple implementations, equivalent alterations and modifications will occur to others skilled in the art based at least in part upon a reading and understanding of this specification and the annexed drawings. The disclosure includes all such modifications and alterations and is limited only by the concept of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or multiple other features of the other implementations as may be desired and advantageous for any given or particular application.

1. A semiconductor device, comprising:
an encapsulation material at least partially encapsulating a semiconductor component of the semiconductor device, wherein the encapsulation material comprises a first side surface, a second side surface opposite to the first side surface and a third side surface connecting the first side surface and the second side surface;
a first plurality of leads protruding out of the first side surface, wherein a first lead is the lead of the first plurality of leads closest to the third side surface; and
a second plurality of leads protruding out of the second side surface, wherein a second lead is the lead of the second plurality of leads closest to the third side surface,
wherein the first lead comprises a first notch aligned with the first side surface and facing the third side surface,
wherein the first notch faces away from a further lead protruding out of the first side surface of the encapsulation material,
wherein the second lead comprises a second notch aligned with the second side surface and facing the third side surface, and
wherein the third side surface is free of any leads and metal.

2. The semiconductor device of claim 1, wherein a first portion of the first notch is arranged outside of the encapsulation material and a second portion of the first notch is encapsulated in the encapsulation material.

3. The semiconductor device of claim 1, wherein the first notch is configured to increase a first creepage distance between the first lead and the second lead, the first creepage distance extending at least partially along the first side surface of the encapsulation material, along the third side surface of the encapsulation material, and at least partially along the second side surface of the encapsulation material.

4. The semiconductor device of claim 1, wherein:
the first notch fully extends along a thickness of the first lead, and
the second notch fully extends along a thickness of the second lead.

5. The semiconductor device of claim 1, wherein:
the first side surface and the second side surface are adjacent to a top surface of the encapsulation material, and
the first notch is one of c-shaped, v-shaped, square-shaped, rectangular-shaped, or tapered when viewed in a direction perpendicular to the top surface.

6. The semiconductor device of claim 1, wherein the first notch extends around the entire circumference of the first lead.

7. The semiconductor device of claim 1, wherein the first notch is configured to provide an interlocking between the first lead and the encapsulation material.

8. The semiconductor device of claim 1, wherein a minimum depth of the first notch is 0.15 mm and a maximum depth of the first notch is 30% of a width of the first lead.

9. The semiconductor device of claim 3, wherein:
the second notch is configured to increase the first creepage distance between the first lead and the second lead along the third side surface of the encapsulation material.

10. The semiconductor device of claim 1, wherein one of the first lead and the second lead is configured to operate in a low voltage domain and the other one of the first lead and the second lead is configured to operate in a high voltage domain.

11. The semiconductor device of claim 1, wherein one of the first lead and the second lead is configured as an input of the semiconductor device and the other one of the first lead and the second lead is configured as an output of the semiconductor device.

12. The semiconductor device of claim 1, comprising:
a first diepad, wherein one of the first lead and the second lead is separate and electrically insulated from the first diepad; and
a second diepad, wherein the other one of the first lead and the second lead is electrically connected to the second diepad, and wherein the second diepad and the other one of the first lead and the second lead are made of a single piece of metal or metal alloy.

13. The semiconductor device of claim 12, comprising:
at least one first semiconductor chip arranged over the first diepad, and
at least one second semiconductor chip arranged over the second diepad,
wherein the at least one first semiconductor chip and the at least one second semiconductor chip are configured to operate as a gate driver, an isolated driver, a digital isolator, a current sensor, or an auxiliary power component.

14. The semiconductor device of claim 3, comprising:
a third lead protruding out of the first side surface of the encapsulation material; and
a fourth lead protruding out of the second side surface of the encapsulation material,
wherein the third lead comprises a third notch aligned with the first side surface of the encapsulation material,
wherein the fourth lead comprises a fourth notch aligned with the second side surface of the encapsulation material, and
wherein the third notch and the fourth notch are configured to increase a second creepage distance between the third lead and the fourth lead, the second creepage distance extending at least partially along the first surface of the encapsulation material, along a fourth side surface of the encapsulation material opposite to the third side surface of the encapsulation material, the fourth side surface connecting the first side surface and the second side surface of the encapsulation material, and at least partially along the second side surface of the encapsulation material.

15. The semiconductor device of claim 14, wherein the fourth side surface of the encapsulation material is free of any leads protruding out of the encapsulation material.

16. The semiconductor device of claim 14, wherein:
the third lead is the lead of the first plurality of leads closest to the fourth side surface of the encapsulation material, and
the fourth lead is the lead of the second plurality of leads closest to the fourth side surface of the encapsulation material.

17. A semiconductor device, comprising:
an encapsulation material at least partially encapsulating a semiconductor component of the semiconductor device;
a first lead protruding out of a first side surface of the encapsulation material; and
a second lead protruding out of a second side surface of the encapsulation material opposite to the first side surface,
wherein a cross section of the first lead tapers towards the first side surface of the encapsulation material and a cross section of the second tapers towards the second side surface of the encapsulation material,
wherein the first lead includes a first portion having a first width and a second portion having a second width smaller than the first width, wherein the second portion is arranged closer to the first side surface than the first portion, and the first portion and the second portion are separated by a dambar, and
wherein the second lead includes a first portion having a first width and a second portion having a second width smaller than the first width, wherein the second portion is arranged closer to the second side surface than the first portion, and the first portion and the second portion are separated by a dambar.

18. A method for manufacturing a semiconductor device, the method comprising:
providing a semiconductor component;
providing a first plurality of leads and a second plurality of leads; and
at least partially encapsulating the semiconductor component, the first plurality of leads and the second plurality of leads in an encapsulation material, wherein the encapsulation material comprises a first side surface, a second side surface opposite to the first side surface and a third side surface connecting the first side surface and the second side surface,
wherein the first plurality of leads protrudes out of the first side surface, wherein a first lead is the lead of the first plurality of leads closest to the third side surface,
wherein the second plurality of leads protrudes out of the second side surface, wherein a second lead is the lead of the second plurality of leads closest to the third side surface,
wherein the first lead comprises a first notch aligned with the first side surface and facing the third side surface,
wherein the first notch faces away from a further lead protruding out of the first side surface of the encapsulation material,
wherein the second lead comprises a second notch aligned with the second side surface and facing the third side surface, and
wherein the third side surface is free of any leads and metal.

19. A method for manufacturing a semiconductor device, the method comprising:
providing a semiconductor component;
providing a first lead and a second lead; and
at least partially encapsulating the semiconductor component, the first lead and the second lead in an encapsulation material,
wherein the first lead protrudes out of a first side surface of the encapsulation material,
wherein the second lead protrudes out of a second side surface of the encapsulation material opposite to the first side surface,
wherein a cross section of the first lead tapers towards the first side surface of the encapsulation material and a cross section of the second tapers towards the second side surface of the encapsulation material,
wherein the first lead includes a first portion having a first width and a second portion having a second width smaller than the first width, wherein the second portion is arranged closer to the first side surface than the first portion, and the first portion and the second portion are separated by a dambar, and
wherein the second lead includes a first portion having a first width and a second portion having a second width smaller than the first width, wherein the second portion is arranged closer to the second side surface than the first portion, and the first portion and the second portion are separated by a dambar.
